(19) United States
(12) Patent Application Publication
(10) Pub. No.: US 2025/0112629 A1
(43) Pub. Date: Apr. 3, 2025

(54) METHODS AND APPARATUS TO STABILIZE POWER FET CIRCUITRY

(71) Applicant: Texas Instruments Incorporated, Dallas, TX (US)

(72) Inventors: Eung Jung Kim, Allen, TX (US); Xiaochun Zhao, Allen, TX (US); Abidur Rahman, Richardson, TX (US); Sualp Aras, Dallas, TX (US)

(21) Appl. No.: 18/374,202

(22) Filed: Sep. 28, 2023

(51) Int. Cl. H03K 17/0812

(52) U.S. Cl. CPC H03K 17/08122

(57) ABSTRACT

An example apparatus includes: a first transistor having a first terminal, a second terminal, and a control terminal; a second transistor having a first terminal, a second terminal, and a control terminal, the first terminal of the second transistor coupled to the first terminal of the first transistor, the second terminal of the second transistor coupled to the second terminal of the first transistor; first driver circuitry having a terminal coupled to the control terminal of the first transistor; second driver circuitry having a terminal coupled to the control terminal of the second transistor; and gate balancing circuitry having a first terminal and a second terminal, the first terminal of the gate balancing circuitry coupled to the control terminal of the first transistor and the terminal of the first driver circuitry, the second terminal of the gate balancing circuitry coupled to the control terminal of the second transistor.

### TECHNICAL FIELD

This description relates generally to transistors and, more particularly, to methods and apparatus to stabilize power FET circuitry.

### BACKGROUND

As electronics continue to advance, designers have become capable of creating devices that consume increasing amounts of power. As such devices become increasingly common, designers have begun to improve power supply circuitry to compensate for increases in power consumption. Such improved power supply circuitry needs to be capable of continuing to supply power across a wide range of operational conditions, such as thermal variations, following over-current events, etc.

### SUMMARY

For methods and apparatus to stabilize power FET circuitry, an example apparatus includes a first transistor having a first terminal, a second terminal, and a control terminal; a second transistor having a first terminal, a second terminal, and a control terminal, the first terminal of the second transistor coupled to the first terminal of the first transistor, the second terminal of the second transistor coupled to the second terminal of the first transistor; first driver circuitry having a terminal coupled to the control terminal of the first transistor; second driver circuitry having a terminal coupled to the control terminal of the second transistor; and gate balancing circuitry having a first terminal and a second terminal, the first terminal of the gate balancing circuitry coupled to the control terminal of the first transistor and the terminal of the first driver circuitry, the second terminal of the gate balancing circuitry coupled to the control terminal of the second transistor.

### BRIEF DESCRIPTION OF THE DRAWINGS

FIG. 1 is a block diagram of example power supply circuitry to supply power to electronic control units from a power source using power FET circuitry.

FIG. 2 is a block diagram of an example of the power FET circuitry of FIG. 1 including gate balancing circuitry and voltage clamp circuitry to control multi-FET power circuitry.

FIG. 3 is a schematic diagram of an example of the power FET circuitry of FIGS. 1 and 2.

FIG. 4 is a schematic diagram of another example implementation of the power FET circuitry of FIGS. 1 and 2 including current sensing circuitry to control the multi-FET power circuitry of FIG. 2.

FIG. 5A is a schematic diagram of the multi-FET power circuitry of FIGS. 2-4, in an example.

FIG. 5B is a diagram of an example implementation of the multi-FET power circuitry of FIGS. 2-5A using an example die layer.

FIG. 6 is a diagram of an example zero temperature coefficient of the multi-FET power circuitry of FIGS. 2-5B across a range of gate-to-source voltages.

FIG. 7 is a flowchart representative of example machine readable instructions and/or example operations that may be executed, instantiated, and/or performed to implement the power FET circuitry of FIGS. 1-5B.

The same reference numbers or other reference designators are used in the drawings to designate the same or similar (functionally and/or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

As electronics continue to advance, designers have become capable of creating devices that consume increasing amounts of power. As such devices become increasingly common, designers have begun to improve power supply circuitry to compensate for increases in power consumption. Such improved power supply circuitry needs to be capable of continuing to supply power across a wide range of operations, such as thermal variations, following over-current events, etc.

Some devices utilize a power field effect transistor (FET) to supply power to a load from a power source. In such devices, turning on the power FET (e.g., enabling, conducting) allows current to flow from the power source to the load. However, as the power FET supplies current to the load, a transconductance of the power FET results in power lost to heat. The amount of power lost to heat increases as the current flowing through the power FET increases. If the heat accumulates, operations of the power FET may begin to vary, or the power FET may become damaged. Some devices prevent such an accumulation using a heat sink to dissipate the heat as it is generated. However, such solutions can be expensive, lead to large device packages, etc. Other devices utilize characteristics of the power FET to reduce creation of heat.

One such characteristic is a zero-temperature coefficient (ZTC), which characterizes regions of operations wherein a power FET is considered to be thermally stable. For an operation of a power FET to be considered thermally stable, when increasing the temperature of the power FET results in a decrease in the current flowing through the power FET. The decrease in the current flowing through the power FET results in the power FET consuming less power, which decreases the temperature. Accordingly, a decrease in the temperature of the power FET allows the device to increase the current. Operating a power FET in such a manner allows for thermal stability and reduces the need for bulky, expensive heat sinks.

Examples described herein include methods and apparatus to stabilize power FET circuitry. In some described examples, the power FET circuitry biases a gate-to-source voltage of a FET responsive to increases in electro-thermal stress. Electro-thermal stress represents an accumulation of heat responsive to power consumption. In such examples, biasing the gate-to-source voltage of the FET increases regions of operation wherein the FET is thermally stable. One such example increase in the electro-thermal stress occurs when the drain-to-source voltage of a power FET increases beyond a threshold voltage. For example, a transconductance of the power FET and the current flowing through the power FET create a drain-to-source voltage that may permanently damage the power FET. During such an operation, the power FET circuitry uses voltage clamp circuitry to bias a gate-to-source voltage of a first power FET while a second power FET is disabled. Advantageously, disabling the second power FET to further bias the gate-to-source voltage of the first power FET increases the thermal stability region of the power FET circuitry to include the increase in the electro-thermal stress.

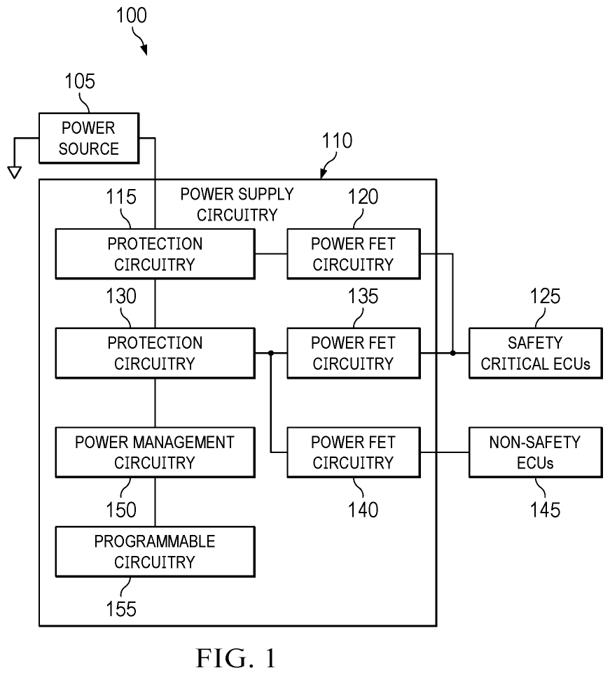

FIG. 1 is a block diagram of an example power supply system 100. In the example of FIG. 1, the power supply system 100 includes an example power source 105, example power supply circuitry 110, first example protection circuitry 115, first example power FET circuitry 120, a first example electronic control unit (ECU) 125, second example protection circuitry 130, second example power FET circuitry 135, third example power FET circuitry 140, a second example ECU 145, example power management circuitry 150, and example programmable circuitry 155. The power supply system 100 uses the power supply circuitry 110 to provide power from the power source 105 to the ECUs 125 and 145.

The power source 105 is coupled to the power supply circuitry 110. The power source 105 supplies power to the power supply circuitry 110. In some examples, the power source 105 is a power storage device, such as a battery. In other examples, the power source 105 represents a grid connection. The power source 105 power to the ECUs 125 and 145 by the power supply circuitry 110.

The power supply circuitry 110 is coupled to the power source 105 and the ECUs 125 and 145. In the example of FIG. 1, the power supply circuitry 110 includes the first protection circuitry 115, the first power FET circuitry 120, the second protection circuitry 130, the second power FET circuitry 135, the third power FET circuitry 140, the power management circuitry 150, and the programmable circuitry 155. The power supply circuitry 110 regulates a supply of power from the power source 105 to the ECUs 125 and 145.

The first protection circuitry 115 is coupled to the power source 105, the first power FET circuitry 120, and the second protection circuitry 130. The first protection circuitry 115 regulates a current supply to the first power FET circuitry 120 and the second protection circuitry 130. In some examples, the first protection circuitry 115 prevents the first power FET circuitry 120 and/or the second protection circuitry 130 from supplying current to the power source 105. For example, the first protection circuitry 115 prevents an inductive and/or capacitive component of the first power FET circuitry 120 from supplying a current to the power source 105. In some examples, the first protection circuitry 115 limits the amount of current the first power FET circuitry 120 sources from the power source 105. In such examples, the first protection circuitry 115 may include current sense circuitry to monitor and/or limit the current from the power source 105.

The first power FET circuitry 120 is coupled to the first protection circuitry 115 and the first ECU 125. The first power FET circuitry 120 receives power from the power source 105 by the first protection circuitry 115. The first power FET circuitry 120 uses a plurality of field effect transistors (FETs) to regulate a supply of power to the first ECU 125. The first power FET circuitry 120 includes circuitry to bias a gate-to-source voltage of the plurality of FETs.

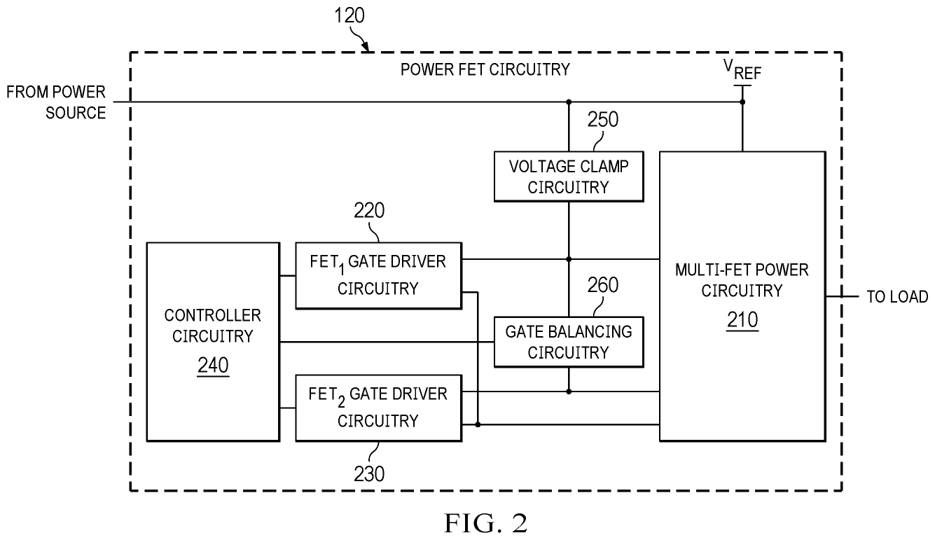

Advantageously, using the plurality of FETs to regulate the supply of power decreases charge accumulation for a given area of the FETs by increasing a total area for which the charge accumulation may be dispersed across. Advantageously, biasing the gate-to-source voltage of the plurality of FETs improves thermal stability of the FETs by decreasing the zero-temperature coefficient. An example implementation of the first power FET circuitry 120 is illustrated and described in FIGS. 2-4, below.

The first ECU 125 is coupled to the power FET circuitries 120 and 135. The power FET circuitries 120 and 135 supply power to the first ECU 125. In the example of FIG. 1, the first ECU 125 represents one or more ECUs configured to control safety features coupled to the power supply system 100. For example, in an automotive application the first ECU 125 may be configured to control airbag deployment, collision detection, etc. In such examples, the first ECU 125 may be coupled to one or more instances of the power FET circuitries 120 and/or 135 to ensure a supply of power is maintained. ECUs, such as the first ECU 125, may be referred to as safety critical ECUs.

The second protection circuitry 130 is coupled to the first protection circuitry 115, the power FET circuitries 135 and 140, and the power management circuitry 150. Alternatively, the power supply circuitry 110 may be modified in accordance with the teachings described herein for the second protection circuitry 130 to be directly coupled to the power source 105. The second protection circuitry 130 regulates a current supply to the power FET circuitries 135 and 140 and the power management circuitry 150. In some examples, the second protection circuitry 130 prevents the power FET circuitries 135 and/or 140 and/or the power management circuitry 150 from supplying current to the first protection circuitry 115 and/or the power source 105. In some examples, the second protection circuitry 130 limits the amount of current the power FET circuitries 135 and 140 source from the power source 105 and/or the first protection circuitry 115. In such examples, the second protection circuitry 130 may include current sense circuitry to monitor and/or limit the current from the power source 105 and/or the first protection circuitry 115.

The second power FET circuitry 135 is coupled to the second protection circuitry 130, the third power FET circuitry 140, and the first ECU 125. The second power FET circuitry 135 receives power from the power source 105 by the second protection circuitry 130. The second power FET circuitry 135 uses a plurality of FETs to regulate a supply of power to the first ECU 125. The second power FET circuitry 135 includes circuitry to bias a gate-to-source voltage of the plurality of FETs. An example implementation of the second power FET circuitry 135 is illustrated and described in FIGS. 2-4, below.

The third power FET circuitry 140 is coupled to the second protection circuitry 130, the second power FET circuitry 135, and the second ECU 145. The third power FET circuitry 140 receives power from the power source 105 by the second protection circuitry 130. The third power FET circuitry 140 uses a plurality of FETs to regulate a supply of power to the second ECU 145. The third power FET circuitry 140 includes circuitry to bias a gate-to-source voltage of the plurality of FETs. An example implementation of the third power FET circuitry 140 is illustrated and described in FIGS. 2-4, below.

The second ECU 145 is coupled to the third power FET circuitry 140. The third power FET circuitry 140 supplies power to the second ECU 145. In the example of FIG. 1, the second ECU 145 represents one or more ECUs configured to control optional and/or non-critical features coupled to the power supply system 100. For example, in an automotive application the second ECU 145 may be configured to control air conditioning, audio systems, etc. ECUs, such as the second ECU 145, may be referred to as non-safety ECUs.

The power management circuitry 150 is coupled to the second protection circuitry 130 and the programmable circuitry 155. In some examples, the power management circuitry 150 may be referred to as a power management integrated circuit (PMIC). The power management circuitry 150 regulates a supply of power to the programmable circuitry 155. In some examples, the power management circuitry 150 steps down (e.g., bucks) a reference voltage supplied by the power source 105 to a supply voltage for the programmable circuitry 155. In such examples, the power management circuitry 150 may be described as power converter circuitry, such as a buck converter, a linear regulator, etc. The power management circuitry 150 supplies power to the programmable circuitry 155.

The programmable circuitry 155 is coupled to the power management circuitry 150. The power management circuitry 150 supplies power to the programmable circuitry 155. The programmable circuitry 155 is configured to instantiate circuitry responsive to an execution of machine-readable instructions. In some examples, the programmable circuitry 155 may be described as processor circuitry.

In the example of FIG. 1, the ECUs 125 and 145 are example loads that may be coupled to the power FET circuitries 120, 135, and/or 140. Alternatively, the power FET circuitries 120, 135, and/or 140 are adaptive to be coupled to alternative loads. In some examples, such as FIG. 2-4, examples of the power FET circuitries 120, 135, and/or 140 are illustrated and described in reference to supplying power to an example load. In such examples, the example load may be the ECUs 125 and/or 145 of FIG. 1 or, in accordance with the teachings described herein, an alternative load.

Additionally, the power supply circuitry 110 and the protection circuitries 115 and 130 are example circuitry representative of example power source circuitry. Alternatively, the power FET circuitries 120, 135, and/or 140 are adaptive to be coupled to a power source that may include protection circuitry, such as the protection circuitries 115 and 130. In some examples, such as FIG. 2-4, examples of the power FET circuitries 120, 135, and/or 140 are illustrated and described in reference to supplying power from an example power supply to an example load. In such an example, the power supply may be the power supply circuitry 110 and the protection circuitries 115 and/or 130. However, the power FET circuitries 120, 135, and/or 140 may modified in accordance with the teachings described herein to be coupled to alternative power supply circuitry.

FIG. 2 is a block diagram of an example of the power FET circuitries 120, 135, and/or 140 of FIG. 1. In the example of FIG. 2, the power FET circuitry 120 includes example multi-FET power circuitry 210, first example FET driver circuitry 220, second example FET driver circuitry 230, example controller circuitry 240, example voltage clamp circuitry 250, and example gate balancing circuitry 260.

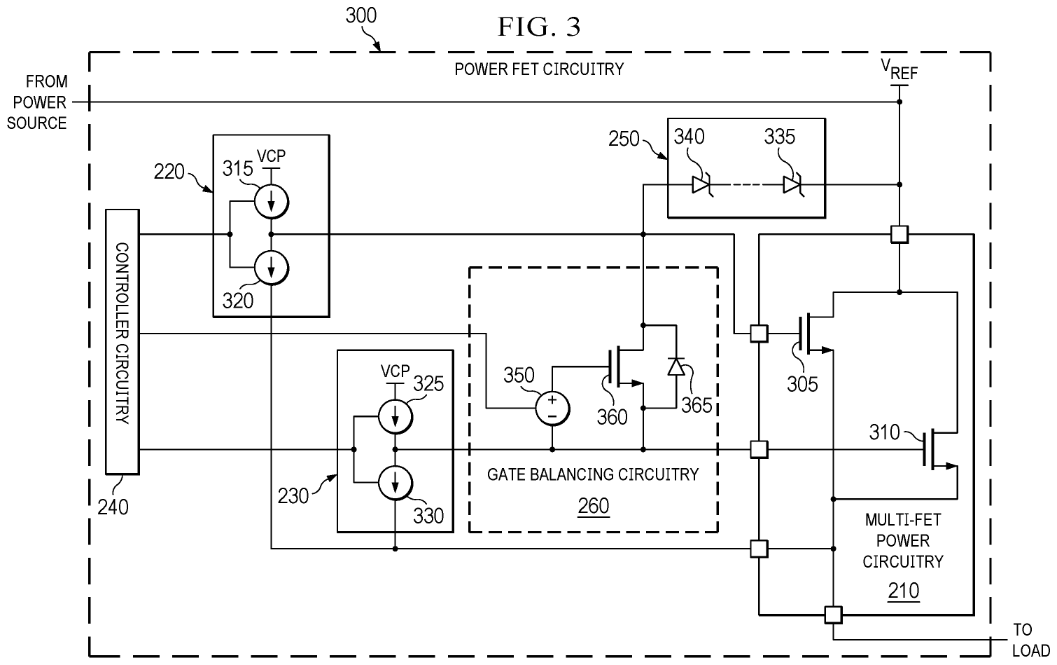

The multi-FET power circuitry 210 is coupled to the first FET driver circuitry 220, the second FET driver circuitry 230, the voltage clamp circuitry 250, and the gate balancing circuitry 260. In the example of FIG. 2, the multi-FET power circuitry 210 is adaptive to be coupled to a power source (e.g., the power source 105 of FIG. 1) and a load (e.g., the ECUs 125 and 145 of FIG. 1). The multi-FET power circuitry 210 allows the load to source power from the power source when enabled. The multi-FET power circuitry 210 prevents the load from sourcing power from the power source when disabled. The FET driver circuitries 220 and 230 control the multi-FET power circuitry 210. An example implementation of the multi-FET power circuitry 210 is illustrated and described in FIG. 3, below.

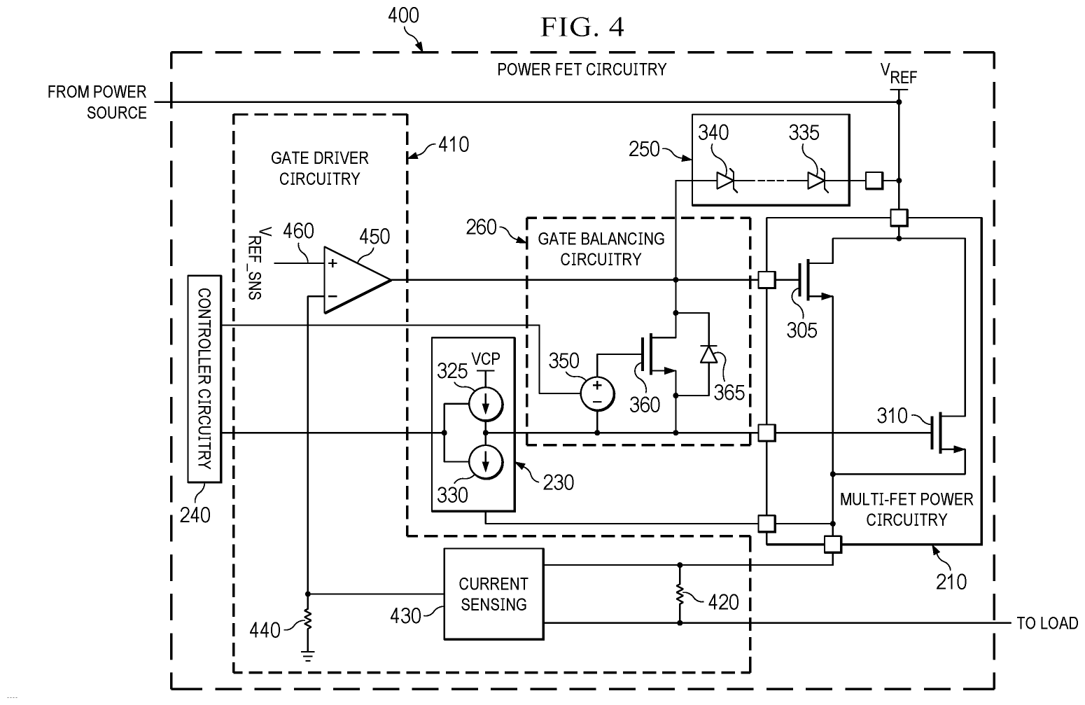

The first FET driver circuitry 220 is coupled to the multi-FET power circuitry 210, the second FET driver circuitry 230, the controller circuitry 240, the voltage clamp circuitry 250, and the gate balancing circuitry 260. The first FET driver circuitry 220 controls a first FET (illustrated in FIGS. 3 and 4, below) of the multi-FET power circuitry 210. In some examples, the first FET driver circuitry 220 enables the first FET of the multi-FET power circuitry 210 by supplying a current to a control terminal of the first FET. In some such examples, the first FET driver circuitry 220 disables the FET of the multi-FET power circuitry 210 by sourcing a current from the control terminal of the first FET. The controller circuitry 240 controls the first FET driver circuitry 220. An example implementation of the first FET driver circuitry 220 is illustrated and described in FIG. 3, below.

The second FET driver circuitry 230 is coupled to the multi-FET power circuitry 210, the first FET driver circuitry 220, the controller circuitry 240, and the gate balancing circuitry 260. The second FET driver circuitry 230 controls a second FET (illustrated in FIGS. 3 and 4, below) of the multi-FET power circuitry 210. In some examples, the second FET driver circuitry 230 enables the second FET of the multi-FET power circuitry 210 by supplying a current to a control terminal of the second FET. In some such examples, the second FET driver circuitry 230 disables the second FET of the multi-FET power circuitry 210 by sourcing a current from the control terminal of the second FET. The controller circuitry 240 controls the second FET driver circuitry 230. An example implementation of the second FET driver circuitry 230 is illustrated and described in FIG. 3, below.

In the example of FIG. 2, the power FET circuitry 120 includes the FET driver circuitries 220 and 230 to control two FETs of the multi-FET power circuitry 210. Alternatively, the power FET circuitry 120 may be modified in accordance with the teachings described herein to control one or more additional FETs of the multi-FET power circuitry 210.

The controller circuitry 240 is coupled to the first FET driver circuitry 220, the second FET driver circuitry 230, and the gate balancing circuitry 260. The controller circuitry 240 controls the FET driver circuitries 220 and 230 and the gate balancing circuitry 260. The controller circuitry 240 controls the multi-FET power circuitry 210 using the FET driver circuitries 220 and 230 and the gate balancing circuitry 260. Advantageously, the controller circuitry 240 may control a supply of power to a load by configuring the FET driver circuitries 220 and 230 and the gate balancing circuitry 260.

The voltage clamp circuitry 250 is coupled to the multi-FET power circuitry 210, the first FET driver circuitry 220, and the gate balancing circuitry 260. In the example of FIG. 2, the voltage clamp circuitry 250 is adaptive to be coupled to a power source (e.g., the power source 105). The voltage clamp circuitry 250 receives the reference voltage from the power source. The voltage clamp circuitry 250 is configured to clamp the first FET driver circuitry 220 and the gate balancing circuitry 260 to the reference voltage responsive to a voltage applied across the voltage clamp circuitry 250. Such a voltage may be referred to as a threshold voltage, a breakdown voltage, a maximum voltage, etc. The voltage clamp circuitry 250 may be referred to as VDS clamp circuitry. The voltage clamp circuitry 250 may partially enable the multi-FET power circuitry 210 by clamping the reference voltage to the first FET driver circuitry 220. An example implementation of the voltage clamp circuitry 250 is illustrated and described in FIG. 3, below.

The gate balancing circuitry 260 is coupled to the multi-FET power circuitry 210, the first FET driver circuitry 220, the second FET driver circuitry 230, the controller circuitry 240, and the voltage clamp circuitry 250. The controller circuitry 240 controls the gate balancing circuitry 260. The gate balancing circuitry 260 sets voltages applied to the multi-FET power circuitry 210 by the FET driver circuitries 220 and 230 approximately equal to each other when enabled. The gate balancing circuitry 260 allows the FET driver circuitries 220 and 230 to individually control the voltages applied to the multi-FET power circuitry 210 when disabled. Advantageously, the voltage clamp circuitry 250 may clamp a voltage generated by the first FET driver circuitry 220 without clamping a voltage generated by the second FET driver circuitry 230. An example implementation of the gate balancing circuitry 260 is illustrated and described in FIG. 3, below.

In an example operation to cause the multi-FET power circuitry 210 to supply current to the load, the controller circuitry 240 configures the FET driver circuitries 220 to supply current to the multi-FET power circuitry 210. The current generates gate-to-source voltages that enables FETs of the multi-FET power circuitry 210. In such an example operation, the controller circuitry 240 enables the gate balancing circuitry 260. While enabled, the gate balancing circuitry 260 uses current from the FET driver circuitries 220 and 230 to increase the gate-to-source voltages of the FETs of the multi-FET power circuitry 210 at approximately the same rate. Such an example operation may be referred to as turning on (e.g., enabling) the power FET circuitry 120.

In an example operation to prevent the multi-FET power circuitry 210 from supplying current to the load, the controller circuitry 240 configures the FET driver circuitries 220 to sink current from the multi-FET power circuitry 210. The FET driver circuitries 220 and 230 sink the current to decrease the gate-to-source voltages of the FETs of the multi-FET power circuitry 210 to a voltage that disables the FETs. In such an example operation, the controller circuitry 240 disables the gate balancing circuitry 260. While disabled, the gate balancing circuitry 260 prevents the second FET driver circuitry 230 from sinking a current from the first FET driver circuitry 220 and the voltage clamp circuitry 250. Such an example operation may be referred to as turning off (e.g., disabling) the power FET circuitry 120.

In some example operations, the multi-FET power circuitry 210 has excessive electro-thermal stress capable of permanently damaging FETs of the multi-FET power circuitry 210. One such example operation occurs when a variation in the load results in a relatively large increase in a voltage drop across the multi-FET power circuitry 210. For example, an output voltage of the multi-FET power circuitry 210 decreases responsive to an inductive portion of the load (e.g., an inductance of a connector). In such example operations, the multi-FET power circuitry 210 attempts to increase a current supplied to the load to compensate for the voltage difference. The controller circuitry 240 configures the FET driver circuitries 220 to sink current from the multi-FET power circuitry 210 responsive to the increase in the current being supplied.

Once the FET driver circuitries 220 and 230 begin to sink current from the multi-FET power circuitry 210, the difference between the reference voltage and the output voltage causes the voltage clamp circuitry 250 to clamp. The voltage clamp circuitry 250 allows the first FET driver circuitry 220 to sink current from the power source, while biasing the multi-FET power circuitry 210 to the reference voltage. Such a bias partially enables the multi-FET power circuitry 210. Such an example operation may be referred to as an overcurrent event of the power FET circuitry 120.

Advantageously, biasing FETs of the multi-FET power circuitry 210 using the reference voltage, increases the thermal stability region of the FETs. Advantageously, the reference voltage may be configured to increase the thermal stability region to account for increases in the output voltage and prevent thermal runaway. Advantageously, the power FET circuitry 120 may continue to operate following an over current event responsive to the voltage clamp circuitry 250. Advantageously, the gate balancing circuitry 260 allows the multi-FET power circuitry 210 to disable one or more FETs to further increase the thermal stability of the FETs coupled to the reference voltage by the voltage clamp circuitry 250.

FIG. 3 is a schematic diagram of example power FET circuitry 300. The power FET circuitry 300 is an example implementation of the power FET circuitries 120, 135, and/or 140 of FIGS. 1 and 2. In the example of FIG. 3, the power FET circuitry 300 includes example implementations of the multi-FET power circuitry 210 of FIG. 2, the first FET driver circuitry 220 of FIG. 2, the second FET driver circuitry 230 of FIG. 2, the controller circuitry 240 of FIG. 2, the voltage clamp circuitry 250 of FIG. 2, and the gate balancing circuitry 260 of FIG. 2.

The multi-FET power circuitry 210 is coupled to the first FET driver circuitry 220, the second FET driver circuitry 230, the voltage clamp circuitry 250, and the gate balancing circuitry 260. In the example of FIG. 3, the multi-FET power circuitry 210 includes a first example transistor 305 and a second example transistor 310.

The first FET driver circuitry 220 is coupled to the multi-FET power circuitry 210, the second FET driver circuitry 230, the controller circuitry 240, the voltage clamp circuitry 250, and the gate balancing circuitry 260. In the example of FIG. 3, the first FET driver circuitry 220 includes first example current source circuitry 315 and second example current source circuitry 320.

The second FET driver circuitry 230 is coupled to the multi-FET power circuitry 210, the first FET driver circuitry 220, the controller circuitry 240, and the gate balancing circuitry 260. In the example of FIG. 3, the second FET driver circuitry 230 includes third example current source circuitry 325 and fourth example current source circuitry 330.

The controller circuitry 240 is coupled to the first FET driver circuitry 220, the second FET driver circuitry 230, and the gate balancing circuitry 260.

The voltage clamp circuitry 250 is coupled to the multi-FET power circuitry 210, the first FET driver circuitry 220, and the gate balancing circuitry 260. In the example of FIG. 3, the voltage clamp circuitry 250 includes a first example diode 335 and a second example diode 340. Alternatively, the voltage clamp circuitry 250 may be modified in accordance with the teachings described herein to include one or more diodes.

The gate balancing circuitry 260 is coupled to the multi-FET power circuitry 210, the first FET driver circuitry 220, the second FET driver circuitry 230, the controller circuitry 240, and the voltage clamp circuitry 250. In the example of FIG. 3, the gate balancing circuitry 260 includes an example voltage source 350 and a third example transistor 360.

The first transistor 305 has a first terminal coupled to the second transistor 310 and adaptive to be coupled to a power source. The first transistor 305 has a second terminal coupled to the second transistor 310, the FET driver circuitries 220 and 230, and adaptive to be coupled to a load. The first transistor 305 has a control terminal coupled to the first FET driver circuitry 220, the voltage clamp circuitry 250, and the gate balancing circuitry 260. The first FET driver circuitry 220 controls the first transistor 305. In some examples, the first FET driver circuitry 220 controls the first transistor 305 by modifying a gate-to-source voltage of the first transistor 305. The first transistor 305 allows a first current to flow from the power source to the load when enabled. The first transistor 305 prevents a flow of current from the power source to the load when disabled.

In the example of FIG. 3, the first transistor 305 is an n-channel field-effect transistor (FET). Alternatively, the first transistor 305 may be an n-channel metal-oxide semiconductor field-effect transistor (MOSFET), an n-channel insulated-gate bipolar transistor (IGBT), an n-channel junction field effect transistor (JFET), an NPN bipolar junction transistor (BJT) and/or, with slight modifications, a p-type equivalent device.

The second transistor 310 has a first terminal coupled to the first transistor 305 and adaptive to be coupled to a power source. The second transistor 310 has a second terminal coupled to the first transistor 305, the FET driver circuitries 220 and 230, and adaptive to be coupled to a load. The second transistor 310 has a control terminal coupled to the second FET driver circuitry 230 and the gate balancing circuitry 260. The second FET driver circuitry 230 controls the second transistor 310. In some examples, the second FET driver circuitry 230 controls the second transistor 310 by modifying a gate-to-source voltage of the second transistor 310. The second transistor 310 allows a second current to flow from the power source to the load when enabled. The second transistor 310 prevents a flow of current from the power source to the load when disabled.

In the example of FIG. 3, the second transistor 310 is an n-channel FET. Alternatively, the second transistor 310 may be an n-channel MOSFET, an n-channel IGBT, an n-channel JFET, an NPN BJT and/or, with slight modifications, a p-type equivalent device.

Transconductances of the transistors 305 and 310 correspond to internal resistances of the transistors 305 and 310. The internal resistances of the transistors 305 and 310 generate a voltage difference across the transistors 305 and 310. The multi-FET power circuitry 210 consumes power by generating heat. The power consumption of the multi-FET power circuitry 210 is approximately equal to the voltage difference times current flowing through the transistors 305 and 310. Accordingly, increasing the current flowing through the transistors 305 and/or 310 increases an electro-thermal stress by generating additional heat.

Advantageously, coupling the transistors 305 and 310 in parallel reduces an internal resistance of the multi-FET power circuitry 210. Advantageously, reducing the internal resistance of the multi-FET power circuitry 210 decreases power consumption and reduces electro-thermal stress. Advantageously, decreasing the current flowing through the transistors 305 and 310 decreases power consumption and reduces electro-thermal stress.

The first current source circuitry 315 has a first terminal coupled to a fixed voltage (V_{CP}). The first current source circuitry 315 has a second terminal coupled to the multi-FET power circuitry 210, the voltage clamp circuitry 250, the gate balancing circuitry 260, and the second current source circuitry 320. The first current source circuitry 315 has a control terminal coupled to the controller circuitry 240. The controller circuitry 240 controls the first current source circuitry 315. The first current source circuitry 315 supplies current to the multi-FET power circuitry 210, the voltage clamp circuitry 250, the gate balancing circuitry 260, and/or the second current source circuitry 320 when enabled. The first current source circuitry 315 prevents a supply of current from the fixed voltage when disabled.

The second current source circuitry 320 has a first terminal coupled to the multi-FET power circuitry 210, the voltage clamp circuitry 250, the gate balancing circuitry 260, and the first current source circuitry 315. The second current source circuitry 320 has a second terminal coupled to the multi-FET power circuitry 210, the second FET driver circuitry 230, and adaptive to be coupled to a load. The second current source circuitry 320 has a control terminal coupled to the controller circuitry 240. The controller circuitry 240 controls the second current source circuitry 320. The second current source circuitry 320 sinks current from the multi-FET power circuitry 210, the voltage clamp circuitry 250, the gate balancing circuitry 260, and/or the first current source circuitry 315 when enabled. The second current source circuitry 320 supplies the current to the load when enabled. The second current source circuitry 320 prevents current from being supplied to the load when disabled.

In the example of FIG. 3, the controller circuitry 240 may enable the first transistor 305 by enabling the first current source circuitry 315 and disabling the second current source circuitry 320. In such examples, the controller circuitry 240 may disable the first transistor 305 by disabling the first current source circuitry 315 and enabling the second current source circuitry 320.

The third current source circuitry 325 has a first terminal coupled to the fixed voltage. The second current source circuitry 325 has a second terminal coupled to the multi-FET power circuitry 210, the gate balancing circuitry 260, and the fourth current source circuitry 330. The third current source circuitry 325 has a control terminal coupled to the controller circuitry 240. The controller circuitry 240 controls the third current source circuitry 325. The third current source circuitry 325 supplies current to the multi-FET power circuitry 210, the gate balancing circuitry 260, and/or the fourth current source circuitry 330 when enabled. The third current source circuitry 325 prevents a supply of current from the fixed voltage when disabled.

The fourth current source circuitry 330 has a first terminal coupled to the multi-FET power circuitry 210, the gate balancing circuitry 260, and the third current source circuitry 325. The fourth current source circuitry 330 has a second terminal coupled to the multi-FET power circuitry 210, the first FET driver circuitry 220, and adaptive to be coupled to a load. The fourth current source circuitry 330 has a control terminal coupled to the controller circuitry 240. The controller circuitry 240 controls the fourth current source circuitry 330. The fourth current source circuitry 330 sinks current from the multi-FET power circuitry 210 the gate balancing circuitry 260, and/or the third current source circuitry 325 when enabled. The fourth current source circuitry 330 supplies the current to the load when enabled. The fourth current source circuitry 330 prevents current from being supplied to the load when disabled.

In the example of FIG. 3, the controller circuitry 240 may enable the second transistor 310 by enabling the third current source circuitry 325 and disabling the fourth current source circuitry 330. In such examples, the controller circuitry 240 may disable the second transistor 310 by disabling the third current source circuitry 325 and enabling the fourth current source circuitry 330.

The first diode 335 has a first terminal coupled to the multi-FET power circuitry 210 and adaptive to be coupled to a power source. The first diode 335 has a second terminal configured to be coupled to the second diode 340. In some examples, the first diode 335 may be coupled to the second diode 340 by one or more additional diodes. The first diode 335 breaks down responsive to a voltage difference greater than or equal to a breakdown voltage across the first diode 335. The first diode 335 supplies approximately the reference voltage from the power source to the second diode 340 when broken down. In some examples, the voltage applied to the second diode 340 is approximately equal to the reference voltage minus a diode voltage drop of the first diode 335. The first diode 335 prevents current from flowing to the second diode 340 when not broken down. The first diode 335 allows the current to flow to the power source and/or the multi-FET power circuitry 210 when forward biased. In the example of FIG. 3, the first diode 335 is a Zener diode. Alternatively, in accordance with the teachings described herein the first diode 335 may be a Schottky diode, or similar circuitry.

The second diode 340 has a first terminal configured to be coupled to the first diode 335. The second diode 340 has a second terminal coupled to the multi-FET power circuitry 210, the first FET driver circuitry 220, and the gate balancing circuitry 260. The second diode 340 breaks down responsive to a voltage difference greater than or equal to a breakdown voltage across the second diode 340. The second diode 340 supplies approximately the reference voltage from the first diode 335 to the multi-FET power circuitry 210, the first FET driver circuitry 220, and/or the gate balancing circuitry 260 when broken down. In some examples, the voltage applied to the multi-FET power circuitry 210, the first FET driver circuitry 220, and/or the gate balancing circuitry 260 is approximately equal to the reference voltage minus a diode voltage drop of the diodes 335 and 340. The second diode 340 prevents current from flowing to the multi-FET power circuitry 210, the first FET driver circuitry 220, and/or the gate balancing circuitry 260 when not broken down. The second diode 340 allows the current to flow to the first diode 335 when forward biased. In the example of FIG. 3, the second diode 340 is a Zener diode. Alternatively, in accordance with the teachings described herein the second diode 340 may be a Schottky diode, or similar circuitry.

In an example operation, the voltage clamp circuitry 250 supplies approximately the reference voltage to the multi-FET power circuitry 210, the first FET driver circuitry 220, and/or the gate balancing circuitry 260 when a voltage difference across the diodes 335 and 340 is approximately greater than or equal to a total breakdown voltage. In such example operations, the electro-thermal stress across the multi-FET power circuitry 210 increases as the voltage difference across the diodes 335 and 340 increases. The total breakdown voltage of the voltage clamp circuitry 250 is approximately equal to an addition of the breakdown voltage of the first diode 335 and the breakdown voltage of the second diode 340. In some examples, the total breakdown voltage of the voltage clamp circuitry 250 may be modified by including one or more diodes, such as one or more instances of the diodes 335 and 340. Such an example operation may be referred to as clamping the reference voltage.

In another example operation, the voltage clamp circuitry 250 prevents the reference voltage from being supplied to the multi-FET power circuitry 210, the first FET driver circuitry 220, and/or the gate balancing circuitry 260 when a voltage difference across the diodes 335 and 340 is less than the total breakdown voltage. In such example operations, the electro-thermal stress across the multi-FET power circuitry 210 decreases as the voltage difference across the diodes 335 and 340 decreases. Such an example operation may be referred to as the voltage clamp circuitry 250 unclamping the reference voltage.

Advantageously, the diodes 335 and 340 may be modified to set the total breakdown voltage of the voltage clamp circuitry 250. Advantageously, the total breakdown voltage of the voltage clamp circuitry 250 may be set to a voltage corresponding to an electro-thermal stress. Advantageously, the diodes 335 and 340 unclamp the reference voltage responsive to the voltage difference across the voltage clamp circuitry 250 decreasing below the total breakdown voltage.

The voltage source 350 has a first terminal coupled to the third transistor 360. The voltage source 350 has a second terminal coupled to the multi-FET power circuitry 210, the second FET driver circuitry 230, and the third transistor 360. The voltage source 350 has a control terminal coupled to the controller circuitry 240. The controller circuitry 240 controls the voltage source 350. The voltage source 350 sets a gate-to-source voltage of the third transistor 360. The voltage source 350 enables the third transistor 360 when enabled. The voltage source 350 disables the third transistor 360 when disabled.

The third transistor 360 has a first terminal coupled to the multi-FET power circuitry 210, the first FET driver circuitry 220, and the voltage clamp circuitry 250. The third transistor 360 has a second terminal coupled to the multi-FET power circuitry 210, the second FET driver circuitry 230, and the voltage source 350. The voltage source 350 controls the third transistor 360. The third transistor 360 allows current to flow from the first terminal of the third transistor 360 to the second terminal of the third transistor 360 when enabled. The third transistor 360 prevents a flow of current from the first terminal of the third transistor 360 to the second terminal of the third transistor 360 when disabled.

In the example of FIG. 3, the third transistor 360 is an n-channel FET. Alternatively, the third transistor 360 may be an n-channel MOSFET, an n-channel IGBT, an n-channel JFET, an NPN BJT and/or, with slight modifications, a p-type equivalent device.

The third transistor 360 has an example body diode 365. In the example of FIG. 3, the body diode 365 is shown for illustrative purposes. Alternatively, the body diode 365 may not be shown. The body diode 365 has a first terminal coupled to the first terminal of the third transistor 360. The body diode 365 has a second terminal coupled to the second terminal of the third transistor 360. The body diode 365 allows current to flow from the second terminal of the third transistor 360 to the first terminal of the third transistor 360 when forward biased.

In an example operation to supply power to a load, the controller circuitry 240 enables the current source circuitries 315, 325, and the voltage source 350. Once enabled, currents from the current source circuitries 315 and 325 increase the gate voltages of the transistors 305 and 310. The voltage source 350 enables the third transistor 360 responsive to being enabled by the controller circuitry 240. The third transistor 360 balances the increase in the gate voltages of the transistors 305 and 310 by allowing the currents from the current source circuitries 315 and 325 to flow across the third transistor 360. For example, current from the first current source circuitry 315 flows through the third transistor 360 to increase the gate voltage of the second transistor 310 when the gate voltage of the second transistor 310 is less than the gate voltage of the first transistor 305. In another example, current from the third current source circuitry 325 flows through the body diode 365 of the third transistor 360 to increase the gate voltage of the first transistor 305 when the gate voltage of the first transistor 305 is less than the gate voltage of the second transistor 310.

In an example operation, the controller circuitry 240 disables the voltage source 350 to disable the third transistor 360. The voltage clamp circuitry 250 clamps the gate voltage of the first transistor 305 without clamping the gate voltage of the second transistor 310 while the third transistor 360 is disabled.

Advantageously, the third transistor 360 allows the gate balancing circuitry 260 to balance the gate voltage of the transistors 305 and 310 when the gate voltage of the first transistor 305 is greater than the gate voltage of the second transistor 310. Advantageously, the body diode 365 allows the gate balancing circuitry 260 to balance the gate voltage of the transistors 305 and 310 when the gate voltage of the first transistor 305 is less than the gate voltage of the second transistor 310. Advantageously, the controller circuitry 240 disables the voltage source 350 to prevent the third transistor 360 from balancing the gate voltages of the transistors 305 and 310 when the gate voltage of the first transistor 305 is greater than the gate voltage of the second transistor 310. Advantageously, the gate balancing circuitry 260 allows the voltage clamp circuitry 250 to bias the gate voltage of the first transistor 305 while the second transistor 310 is disabled.

FIG. 4 is a schematic diagram of example power FET circuitry 400. The power FET circuitry 400 is another example implementation of the power FET circuitries 120, 135, and/or 140 of FIGS. 1-3. In the example of FIG. 4, the power FET circuitry 400 includes the multi-FET power circuitry 210 of FIGS. 2 and 3, the second FET driver circuitry 230 of FIGS. 2 and 3, the controller circuitry 240 of FIGS. 2 and 3, the voltage clamp circuitry 250 of FIGS. 2 and 3, the gate balancing circuitry 260 of FIGS. 2 and 3, and third example FET driver circuitry 410.

The third FET driver circuitry 410 is coupled to the multi-FET power circuitry 210, the second FET driver circuitry 230, the voltage clamp circuitry 250, the gate balancing circuitry 260, and adaptive to be coupled to a load (e.g., the ECUs 125 and/or 145 of FIG. 1). In the example of FIG. 4, the third FET driver circuitry 410 includes a first example resistor 420, example current sense circuitry 430, a second example resistor 440, an example amplifier 450, and an example reference sense voltage 460. The third FET driver circuitry 410 is an alternate implementation of the first FET driver circuitry 220 of FIGS. 2 and 3.

The first resistor 420 has a first terminal coupled to the multi-FET power circuitry 210, the second FET driver circuitry 230, and the current sense circuitry 430. The first resistor 420 has a second terminal coupled to the current sense circuitry 430 and adaptive to be coupled to a load. The first resistor 420 has a relatively small resistance. The first resistor 420 generates a voltage difference proportional to an output current from the multi-FET power circuitry 210 times the relatively small resistance of the first resistor 420. Advantageously, reducing the resistance of the first resistor 420 decreases power consumption. In some examples, the first resistor 420 may be referred to as a sense resistor.

The current sense circuitry 430 has a first terminal coupled to the multi-FET power circuitry 210, the second FET driver circuitry 230, and the first resistor 420. The current sense circuitry 430 has a second terminal coupled to the first resistor 420 and adaptive to be coupled to a load. The current sense circuitry 430 has a third terminal coupled to the second resistor 440 and the amplifier 450. The current sense circuitry 430 determines the voltage difference across the first resistor 420. In some examples, the current sense circuitry 430 may include a differential amplifier. The current sense circuitry 430 generates a sense current based on the voltage difference across the first resistor 420. The current sense circuitry 430 supplies the sense current to the second resistor 440 and/or the amplifier 450.

The second resistor 440 has a first terminal coupled to the current sense circuitry 430 and the amplifier 450. The second resistor 440 has a second terminal coupled to a common terminal that provides a common potential (e.g., ground). The second resistor 440 has a resistance. The second resistor 440 receives the sense current from the current sense circuitry 430. The second resistor 440 generates a sense voltage based on the sense current from the current sense circuitry 430 and the resistance of the second resistor 440. The second resistor 440 supplies the sense voltage to the amplifier 450. Advantageously, the sense voltage represents the output current of the multi-FET power circuitry 210.

The amplifier 450 has a first input coupled to the current sense circuitry 430 and the second resistor 440. The amplifier 450 has a second input coupled to the reference sense voltage 460. The amplifier 450 has an output coupled to the multi-FET power circuitry 210, the voltage clamp circuitry 250, and the gate balancing circuitry 260. The amplifier 450 receives the sense voltage from the second resistor 440. The amplifier 450 compares the sense voltage to the reference sense voltage 460. The amplifier 450 enables the first transistor 305 responsive to a determination that the sense voltage is less than the reference sense voltage 460. Such a determination represents that the output current of the multi-FET power circuitry 210 is less than a maximum current output of the multi-FET power circuitry 210. The amplifier 450 disables the first transistor 305 responsive to a determination that the sense voltage is greater than the reference sense voltage 460. Such a determination represents that the output current of the multi-FET power circuitry 210 is greater than or equal to the maximum current output of the multi-FET power circuitry 210.

In an example operation where the output current of the multi-FET power circuitry 210 increases due to excessive electro-thermal stress, the first resistor 420 generates a voltage difference based on the increased output current of the multi-FET power circuitry 210. The current sense circuitry 430 causes the second resistor 440 to generate the sense voltage using a sense current that is proportional to the increased output current. In such an example operation, the amplifier 450 determines that the sense voltage is greater than the reference sense voltage 460. The amplifier 450 decreases the gate voltage of the first transistor 305 responsive to the sense voltage being greater than the reference sense voltage 460. The voltage clamp circuitry 250 clamps the refence voltage responsive to the decrease in the gate voltage of the first transistor 305.

Advantageously, the voltage clamp circuitry 250 increases the thermal stability of the multi-FET power circuitry 210 by clamping the gate voltage of the first transistor 305. Advantageously, clamping the gate voltage of the first transistor 305 to the reference voltage increases the thermal stability of the multi-FET power circuitry 210 by biasing the gate-to-source voltage of the first transistor 305. Advantageously, the multi-FET power circuitry 210 increases the output current responsive to excessive electro-thermal stress. Advantageously, the third FET driver circuitry 410 increases the thermal stability of the multi-FET power circuitry 210 responsive to an increase in the output current.

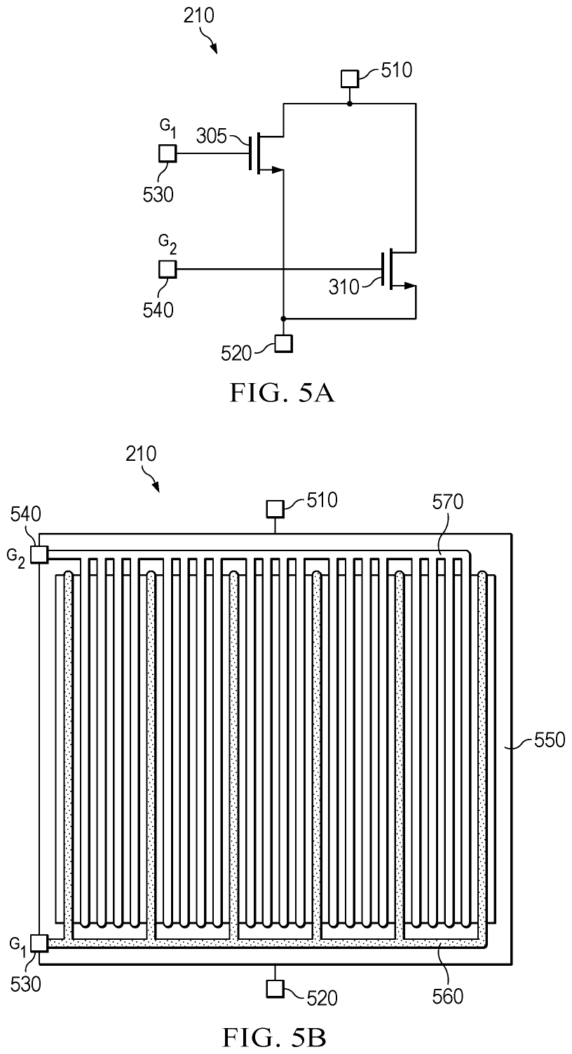

FIG. 5A is a schematic diagram of the multi-FET power circuitry 210 of FIGS. 2-4. In the example of FIG. 5A, the multi-FET power circuitry 210 includes the first transistor 305 of FIGS. 3 and 4, the second transistor 310 of FIGS. 3 and 4, a first example terminal 510, a second example terminal 520, a first example gate terminal 530, and a second example gate terminal 540.

The first transistor 305 has a first terminal coupled to the second transistor 310 and the first terminal 510. The first transistor 305 has a second terminal coupled to the second transistor 310 and the second terminal 520. The first transistor 305 has a control terminal coupled to the first gate terminal 530. In some examples, the first terminal of the first transistor 305 is a drain terminal. In such examples, the second terminal of the first transistor 305 is a source terminal.

The second transistor 310 has a first terminal coupled to the first transistor 305 and the first terminal 510. The second transistor 310 has a second terminal coupled to the first transistor 305 and the second terminal 520. The second transistor 310 has a control terminal coupled to the second gate terminal 540. In some examples, the first terminal of the second transistor 310 is a drain terminal. In such examples, the second terminal of the second transistor 310 is a source terminal.

The first terminal 510 is adaptive to be coupled to a power source (e.g., the power source 105 of FIG. 1). The second terminal 520 is adaptive to be coupled to a load (e.g., the ECUs 125 and/or 145 of FIG. 1). The first gate terminal 530 is adaptive to be coupled to the first FET driver circuitry 220 of FIGS. 2-4, the voltage clamp circuitry 250 of FIGS. 2-4, the gate balancing circuitry 260 of FIGS. 2-4, and/or the third FET driver circuitry 410 of FIG. 4. The second gate terminal 540 is adaptive to be coupled to the second FET driver circuitry 230 of FIGS. 2-4 and/or the gate balancing circuitry 260.

FIG. 5B is a diagram of an example implementation of the multi-FET power circuitry 210 of FIGS. 2-5A using an example die layer 550. In the example of FIG. 5B, the multi-FET power circuitry 210 includes the first terminal 510 of FIG. 5A, the second terminal 520 of FIG. 5A, the first gate 530 of FIG. 5A, the second gate 540 of FIG. 5A, the die layer 550, first example gate routing 560, and second example gate routing 570. In the example of FIG. 5B, the transistors 305 and 310 of FIGS. 3-5A are implemented using the die layer 550. In some examples, the die layer 550 is a silicon die. Alternatively, the die layer 550 may be manufactured using one or more alternative materials. Advantageously, the transistors 305 and 310 may share the die layer 550 responsive to being coupled in parallel.

In the example of FIG. 5B, the first gate routing 560 implements the control terminal of the first transistor 305. The first gate routing 560 electrically routes the first gate terminal 530 through portions of the die layer 550. The first gate routing 560 allows current to flow from the first terminal 510 to the second terminal 520 when the voltage difference between the first gate terminal 530 and the second terminal 520 is greater than a threshold voltage of the first transistor 305. The first gate routing 560 includes a plurality of routes evenly spread across the die layer 550. Each of the plurality of routes of the first gate routing 560 allow charges to evenly disperse across the die layer 550. Advantageously, the first gate routing 560 allows charges of the current flowing between the terminals 510 and 520 to spread out across the die layer 550.

In the example of FIG. 5B, the second gate routing 570 implements the control terminal of the second transistor 310. The second gate routing 570 electrically routes the second gate terminal 540 through portions of the die layer 550. The second gate routing 570 allows current to flow from the first terminal 510 to the second terminal 520 when the voltage difference between the second gate terminal 540 and the second terminal 520 is greater than a threshold voltage of the second transistor 3110. The second gate routing 570 includes a plurality of routes spread across the die layer 550. Each of the plurality of routes of the second gate routing 570 disperses charges across the die layer 550. Advantageously, the second gate routing 570 allows charges of the current flowing between the terminals 510 and 520 to spread out across the die layer 550.

In the example of FIG. 5B, the amount of current allowed to flow between the terminals 510 and 520 is proportional to the length of the gate routings 560 and 570. In an example operation, the first gate routing 560 allows a first current to flow, while the second gate routing 570 allows a second current to flow. In such an example operation, the first current is approximately one fourth of the second current responsive to the second gate routing 570 having approximately four times the length of the first gate routing 560.

Alternatively, the lengths of the gate routings 560 and 570 may be modified, in accordance with this description, to allow alternate current ratios. For example, the gate routings 560 and 570 allow the same current to flow when the lengths of the gate routings 560 and 570 are approximately equal. In such an example, the gate routes 560 and 570 switch every route. In such an example, spreading out the gate routings 560 and 570 increases the thermal stability of the multi-FET power circuitry 210.

In another example, the current resulting from the second gate routing 570 may be three times the current resulting from the first gate routing 560. In such an example, the length of the second gate routing 570 is approximately three times the length of the first gate routing 560. Also, the routes of the first gate routing 560 are separated by three routes of the second gate routing 570. Such a separation increases the thermal stability of the multi-FET power circuitry 210.

In an example operation, disabling the second transistor 310 and biasing the gate-to-source voltage of the first transistor 305, allows the charge density of the die layer 550 to increase while the multi-FET power circuitry 210 remains thermally stable. The thermal stability of the multi-FET power circuitry 210 increases as the ratio between the lengths of the gate routings 560 and 570 increases. Advantageously, ratioing the currents of the transistors 305 and 310, by the lengths of the gate routings 560 and 570, increases the thermal stability of the multi-FET power circuitry 210. Advantageously, allowing the charges to spread out across the die layer 550 increases the thermal stability of the first transistor 305 while the second transistor 310 is disabled.

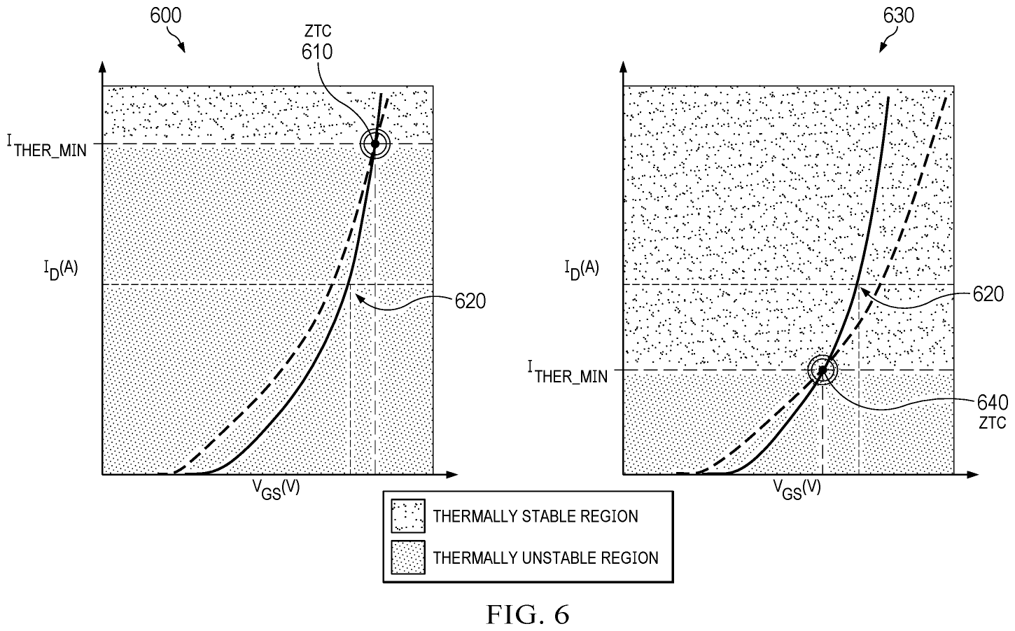

FIG. 6 is a diagram illustrating example thermal stabilities of the multi-FET power circuitry 210 of FIGS. 2-4 across a range of currents and gate-to-source voltages. A first example thermal stability plot 600 illustrates a first example zero temperature coefficient (ZTC) 610. The first ZTC 610 represents a threshold current for thermal stability of the first transistor 305 of FIGS. 3 and 4.

An operation of the first transistor 305 is thermally stable when the current flowing through the first transistor 305 (ID) decreases responsive to an increase in power consumption (e.g., increasing a current flowing through the first transistor 305). An operation of the first transistor 305 is thermally unstable when the current flowing through the first transistor 305 increases and/or does not change responsive to an increase in power consumption. Such an operation results in excessive electro-thermal stress (e.g., accumulation of heat) capable of damaging the first transistor 305. A thermally unstable operation of the first transistor 305 may be referred to as thermal runaway.

The first ZTC 610 is an intersection point of the current-voltage (I-V) plots of the first transistor 305 across different temperatures. The first ZTC 610 characterizes a minimum current (I_{THER_MIN}) needed to be thermally stable. In the first thermal stability plot 600, The first transistor 305 is thermally unstable when supplying a current less than the minimum current of the first ZTC 610. For example, operating the first transistor 305 at a first example conditions 620 results in excessive electro-thermal stress and thermal runaway.

In some example operations, the power FET circuitry 120, 135, 140, 300, and/or 400 of FIGS. 1-4 may need the first transistor 305 to supply a current less than the minimum current of the first ZTC 610. For such examples, reducing the minimum current of the first ZTC 610 would prevent thermal runaway at the first conditions 620.

A second example thermal stability plot 630 illustrates a second example ZTC 640. The second ZTC 640 represents a threshold current for thermal stability of the first transistor 305 when the gate-to-source voltage is biased. For example, the voltage clamp circuitry 250 biases the gate-to-source voltage of the first transistor 305. The second ZTC 640 is an intersection point of the I-V plots of the first transistor 305 across different temperatures while the gate-to-source voltage biased. In the second thermal stability plot 630, the second ZTC 640 characterizes a minimum current (I_{THER_MIN}) needed to be thermally stable. For example, operating the first transistor 305 at the first conditions 620 prevents excessive electro-thermal stress and thermal runaway. In the second thermal stability plot 630, the first transistor 305 is thermally unstable when supplying a current less than the minimum current of the second ZTC 640.

Advantageously, biasing the gate-to-source voltage of the first transistor 305 decreases the minimum current needed to be thermally stable. Advantageously, decreasing the minimum current needed to be thermally stable increases the thermal stability of the first transistor 305.

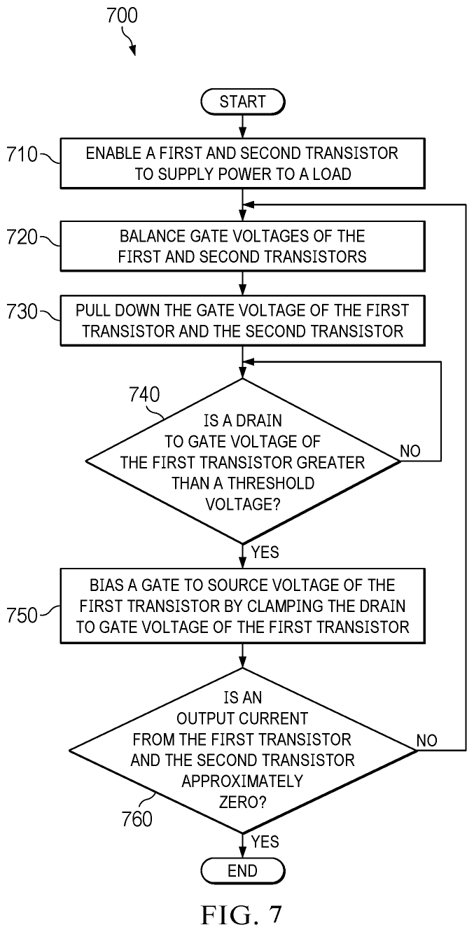

FIG. 7 is a flowchart representative of example machine readable instructions and/or example operations 700 that may be executed, instantiated, and/or performed using an example implementation of the power FET circuitries 120, 135, 140, 300, and/or 400 of FIGS. 1-4. The example machine-readable instructions and/or the example operations 700 of FIG. 7 begin at block 710, at which the FET driver circuitries 220 and 230 of FIGS. 2-4 enable a first and second transistor to supply power to a load. In some examples, the first FET driver circuitry 220 supplies a current to the first transistor 305 of FIGS. 3 and 4 and the second FET driver circuitry 230 supplies a current to the second transistor 310 of FIGS. 3 and 4. In such examples, the transistors 305 and 310 supply a current to the load (e.g., the ECUs 125 and/or 145 of FIG. 1) responsive to the FET driver circuitries 220 and 230 supplying the currents.

The gate balancing circuitry 260 of FIGS. 2-4 balances gate voltages of the first and second transistors. (Block 720). In some examples, gate balancing circuitry 260 balances an increase in the gate voltages of the transistors 305 and 310 by allowing the currents from the current source circuitries 315 and 325 to flow across the third transistor 360 of FIGS. 3 and 4. For example, current from the first current source circuitry 315 flows through the third transistor 360 to increase the gate voltage of the second transistor 310 when the gate voltage of the second transistor 310 is less than the gate voltage of the first transistor 305.

The FET driver circuitries 220 and 230 pull down the gate voltage of the first transistor and the second transistor. (Block 730). In some examples, the controller circuitry 240 of FIGS. 2-4 configured the FET driver circuitries 220 and 230 to source a current from the transistors 305 and 310. In such examples, sourcing the current decreases the gate voltage of the transistor 305 and 310.

The voltage clamp circuitry 250 of FIGS. 2-4 determines if the drain-to-gate voltage of the first transistor is greater than a threshold voltage. (Block 740). In some examples, the voltage clamp circuitry 250 determines if the drain-to-gate voltage of the first transistor 305 is greater than the total breakdown voltage of the voltage clamp circuitry 250. In such examples, the total breakdown voltage is the threshold voltage. Such a total breakdown voltage may be referred to as a clamping threshold voltage. If the voltage clamp circuitry 250 determines that the drain-to-gate voltage of the first transistor is not greater than a threshold voltage (e.g., Block 740 returns a result of No), control proceeds to return to Block 740.

If the voltage clamp circuitry 250 determines that the drain-to-gate voltage of the first transistor is greater than a threshold voltage (e.g., Block 740 returns a result of Yes), the voltage clamp circuitry 250 biases a gate-to-source voltage of the first transistor by clamping the drain-to-gate voltage of the first transistor. (Block 750). In some examples, the voltage clamp circuitry 250 breaks down responsive to a voltage difference approximately equal to the total breakdown voltage of the diodes 335 and 340 of FIGS. 3 and 4.

The voltage clamp circuitry 250 determines if the drain-to-gate voltage of the first transistor is greater than the threshold voltage. (Block 760). In some examples, the voltage clamp circuitry 250 continues to clamp the reference voltage until the drain-to-gate voltage of the first transistor 305 is less than the total breakdown voltage.

If the voltage clamp circuitry 250 determines that the drain-to-gate voltage of the first transistor is not greater than a threshold voltage (e.g., Block 760 returns a result of No), control proceeds to return to Block 730. If the voltage clamp circuitry 250 determines that the drain-to-gate voltage of the first transistor is greater than a threshold voltage (e.g., Block 760 returns a result of Yes), control proceeds to end.

Although example methods are described with reference to the flowchart illustrated in FIG. 7, many other methods of increasing the thermal stability of the multi-FET power circuitry 210 may alternatively be used in accordance with this description. For example, the order of execution of the blocks may be changed, and/or some of the blocks described may be changed, eliminated, or combined. Similarly, additional operations may be included in the manufacturing process before, in between, or after the blocks shown in the illustrated examples.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Numerical identifiers such as “first,” “second,” “third,” etc. are used merely to distinguish between elements of substantially the same type in terms of structure and/or function. These identifiers as used in the detailed description do not necessarily align with those used in the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

What is claimed is:

1. An apparatus comprising:
a first transistor having a first terminal, a second terminal, and a control terminal;
a second transistor having a first terminal, a second terminal, and a control terminal, the first terminal of the second transistor coupled to the first terminal of the first transistor, the second terminal of the second transistor coupled to the second terminal of the first transistor;
first driver circuitry having a terminal coupled to the control terminal of the first transistor;
second driver circuitry having a terminal coupled to the control terminal of the second transistor; and
gate balancing circuitry having a first terminal and a second terminal, the first terminal of the gate balancing circuitry coupled to the control terminal of the first transistor and the terminal of the first driver circuitry, the second terminal of the gate balancing circuitry coupled to the control terminal of the second transistor and the terminal of the second driver circuitry.

2. The apparatus of claim 1, further comprising voltage clamp circuitry having a first terminal and a second terminal, the first terminal of the voltage clamp circuitry coupled to the first terminal of the first transistor and the first terminal of the second transistor, the second terminal of the voltage clamp circuitry coupled to the control terminal of the first transistor, the terminal of the first driver circuitry, and the first terminal of the gate balancing circuitry.

3. The apparatus of claim 2, wherein the voltage clamp circuitry includes at least one Zener diode coupled between the first terminal of the voltage clamp circuitry and the second terminal of the voltage clamp circuitry.

4. The apparatus of claim 1, wherein the terminal of the first driver circuitry is a first terminal, the terminal of the second driver circuitry is a first terminal, the first driver circuitry further having a second terminal, the second driver circuitry further having a second terminal, the second terminal of the first driver circuitry coupled to the second terminal of the first transistor, the second terminal of the second transistor, and the second terminal of the second driver circuitry.

5. The apparatus of claim 1, wherein the first driver circuitry includes:
first current source circuitry having a terminal coupled to the control terminal of the first transistor and the first terminal of the gate balancing circuitry; and
second current source circuitry having a first terminal and a second terminal, the first terminal of the second current source circuitry coupled to the control terminal of the first transistor, the first terminal of the gate balancing circuitry, and the terminal of the first current source circuitry, the second terminal of the second current source circuitry coupled to the second terminal of the first transistor and the second terminal of the second transistor.

6. The apparatus of claim 1, wherein the first driver circuitry includes:
current sensing circuitry having a first terminal and a second terminal, the first terminal of the current sensing circuitry coupled to the second terminal of the first transistor and the second terminal of the second transistor;
a resistor having a terminal coupled to the second terminal of the current sensing circuitry; and
an amplifier having a first terminal and a second terminal, the first terminal of the amplifier coupled to the second terminal of the current sensing circuitry and the terminal of the resistor, the second terminal of the amplifier coupled to the control terminal of the first transistor and the first terminal of the gate balancing circuitry.

7. The apparatus of claim 1, wherein the gate balancing circuitry includes:
current source circuitry having a terminal;
a resistor having a first terminal and a second terminal, the first terminal of the resistor coupled to the terminal of the current source circuitry, the second terminal of the resistor coupled to the control terminal of the second transistor and the terminal of the second driver circuitry; and
a third transistor having a first terminal, a second terminal, a control terminal, and a body diode, the first terminal of the third transistor coupled to the control terminal of the first transistor and the terminal of the first driver circuitry, the second terminal of the third transistor coupled to the control terminal of the second transistor, the terminal of the second driver circuitry, and the second terminal of the resistor, the control terminal of the third transistor coupled to the terminal of the current source circuitry and the first terminal of the resistor, the body diode configured to allow current to flow from the second terminal of the third transistor to the first terminal of the third transistor.

8. A system comprising:
a first transistor having a first terminal, a second terminal, and a control terminal;
a second transistor having a first terminal, a second terminal, and a control terminal, the first terminal of the second transistor coupled to the first terminal of the first transistor, the second terminal of the second transistor coupled to the second terminal of the first transistor; and
gate balancing circuitry including:
current source circuitry having a terminal;
a resistor having a first terminal and a second terminal, the first terminal of the resistor coupled to the terminal of the current source circuitry, the second terminal of the resistor coupled to the control terminal of the second transistor; and
a third transistor having a first terminal, a second terminal, and a control terminal, the first terminal of the third transistor coupled to the control terminal of the first transistor, the second terminal of the third transistor coupled to the control terminal of the second transistor and the second terminal of the resistor, the control terminal of the third transistor coupled to the terminal of the current source circuitry and the first terminal of the resistor.

9. The system of claim 8, further comprising voltage clamp circuitry having a first terminal and a second terminal, the first terminal of the voltage clamp circuitry coupled to the first terminal of the first transistor and the first terminal of the second transistor, the second terminal of the voltage clamp circuitry coupled to the control terminal of the first transistor and the first terminal of the third transistor.

10. The system of claim 9, wherein the voltage clamp circuitry includes at least one Zener diode coupled between the first terminal of the voltage clamp circuitry and the second terminal of the voltage clamp circuitry.

11. The system of claim 8, the system further comprising:
first driver circuitry having a terminal coupled to the control terminal of the first transistor and the first terminal of the third transistor; and
second driver circuitry having a terminal coupled to the control terminal of the second transistor and the second terminal of the third transistor.

12. The system of claim 11, wherein the first driver circuitry includes:
first current source circuitry having a terminal coupled to the control terminal of the first transistor and the first terminal of the gate balancing circuitry; and
second current source circuitry having a first terminal and a second terminal, the first terminal of the second current source circuitry coupled to the control terminal of the first transistor, the first terminal of the gate balancing circuitry, and the terminal of the first current source circuitry, the second terminal of the second current source circuitry coupled to the second terminal of the first transistor and the second terminal of the second transistor.

13. The system of claim 11, wherein the first driver circuitry includes:
current sensing circuitry having a first terminal and a second terminal, the first terminal of the current sensing circuitry coupled to the second terminal of the first transistor and the second terminal of the second transistor;
a resistor having a terminal coupled to the second terminal of the current sensing circuitry; and
an amplifier having a first terminal and a second terminal, the first terminal of the amplifier coupled to the second terminal of the current sensing circuitry and the terminal of the resistor, the second terminal of the amplifier coupled to the control terminal of the first transistor and the first terminal of the gate balancing circuitry.

14. The system of claim 8, wherein the third transistor further includes a body diode configured to allow current to flow from the second terminal of the third transistor to the first terminal of the third transistor.

15. A device comprising:
a first transistor having a first terminal, a second terminal, and a control terminal;
a second transistor having a first terminal, a second terminal, and a control terminal, the first terminal of the second transistor coupled to the first terminal of the first transistor, the second terminal of the second transistor coupled to the second terminal of the first transistor;
voltage clamp circuitry having a first terminal and a second terminal, the first terminal of the voltage clamp circuitry coupled to the first terminal of the first transistor and the first terminal of the second transistor, the second terminal of the voltage clamp circuitry coupled to the control terminal of the first transistor; and
gate balancing circuitry configured to:
set a first voltage of the control terminal of the first transistor equal to a second voltage of the control terminal of the second transistor;
allow the voltage clamp circuitry to clamp the control terminal of the first transistor; and
prevent the voltage clamp circuitry from clamping the control terminal of the second transistor.

16. The device of claim 15, wherein the gate balancing circuitry includes a third transistor configured to control current between the control terminal of the first transistor and the control terminal of the second transistor.

17. The device of claim 16, wherein the gate balancing circuitry is further configured to generate a reference voltage to control the third transistor, the third transistor configured to allow current to flow between the control terminal of the first transistor and the control terminal of the second transistor when enabled, and prevent current from flowing from the control terminal of the first transistor to the control terminal of the second transistor when disabled.

18. The device of claim 16, wherein the first transistor has first gate routing, the second transistor has second gate routing, the device further comprising a die layer including the first gate routing of the first transistor and the second gate routing of the second transistor.

19. The device of claim 15, wherein the voltage clamp circuitry is configured to clamp the control terminal of the first transistor based on a voltage difference between the first terminal of the first transistor and the control terminal of the first transistor.

20. The device of claim 15, wherein the first transistor is configured to supply a first current based on a first voltage of the control terminal of the first transistor, the second transistor is configured to supply a second current based on a second voltage of the control terminal of the second transistor, the first current is proportional to the second current.
